(19) United States
(12) Patent Application Publication
(10) Pub. No.: US 2006/0033533 A1
(43) Pub. Date: Feb. 16, 2006

(54) Semiconductor device

(76) Inventor: Kouji Yamada, Kyoto-shi (JP)

Correspondence Address: FISH & RICHARDSON P.C., P.O. BOX 1022, MINNEAPOLIS, MN, 55440-1022, US

(21) Appl. No.: 11/199,931

(22) Filed: Aug. 8, 2005

(30) Foreign Application Priority Data
Aug. 6, 2004 (JP) 2004-230882

(51) Int. Cl. H03K 19/096

(52) U.S. Cl. 326/95

(57) ABSTRACT

A main circuit includes a first logic circuit behaving as a critical path and a second logic circuit operating comparatively fast. The second logic circuit is fed with a first supply voltage. The first logic circuit is usually fed with a second supply voltage to ensure normal operation of the main circuit. When a clock feed circuit is not feeding a clock, or when an input signal from a signal source remains at a fixed potential, the supply voltage to the first logic circuit is lowered to the first supply voltage.

This application is based on Japanese Patent Application No. 2004-230882 filed on Aug. 6, 2004, the contents of which are hereby incorporated by reference.

### BACKGROUND OF THE INVENTION

1. Field of the Invention

The present invention relates to a semiconductor device such as a semiconductor integrated circuit and to an electric appliance such as a portable device employing such a semiconductor device, more particularly to a semiconductor device having a function for adjusting a supply voltage fed to a circuit including a critical path and to an electric appliance such as a portable device employing such a semiconductor device.

2. Description of Related Art

In general, a circuit path that determines the maximum operating frequency of a semiconductor integrated circuit is called a critical path. Now, the higher the supply voltage fed to the semiconductor integrated circuit, the faster the critical path operates. The problem here is that, although this makes it possible to make higher the maximum operating frequency of the semiconductor integrated circuit, this leads to increased electric power consumption. To overcome this problem, there has conventionally been proposed a technique for achieving a reduction in electric power consumption while increasing the operation speed of the critical path.

For example, Japanese Patent Applications Laid-Open Nos. H5-299624 (hereinafter referred to as Patent Document 1) and H7-249067 (hereinafter referred to as Patent Document 2) disclose techniques for reducing electric power consumption without decreasing the operating frequency of a semiconductor integrated circuit by driving, with a low-voltage source, a low-speed logic circuit that just has to operate at low speed and by driving, with a high-voltage source, a high-speed logic circuit that has to operate at high speed.

However, in the configurations disclosed in the above-mentioned Patent Documents 1 and 2, it is necessary to constantly feed the high-speed logic circuit having a critical path with a comparatively high supply voltage from the high-voltage source. This hampers reduction of electric power consumption.

In view of the conventionally encountered disadvantages mentioned above, an object of the present invention is to provide a semiconductor device that can achieve a reduction in electric power consumption while ensuring normal operation of the semiconductor device, and to provide an electric appliance employing such a semiconductor device.

### SUMMARY OF THE INVENTION

To achieve the above object, according to the present invention, a semiconductor device is provided with: a main circuit including a first logic circuit and a second logic circuit that is connected in a stage preceding or succeeding the first logic circuit and that operates from a first supply voltage equal to or lower than a supply voltage fed to the first logic circuit; and a control circuit that controls the supply voltage fed to the first logic circuit according to a state of an input signal to the first logic circuit.

Specifically, for example, the semiconductor device is further provided with a clock feed circuit that can feed a clock to a flip-flop provided in a stage preceding the first logic circuit, and the control circuit so control that, when the clock feed circuit is feeding the clock, the first logic circuit is fed with a second supply voltage higher than the first supply voltage and, when the clock feed circuit is not feeding the clock, the first logic circuit is fed with the first supply voltage.

When the clock feed circuit is feeding the clock, the first logic circuit is fed with a comparatively high second supply voltage. This makes the first logic circuit operate relatively fast, and thereby ensures normal operation of the main circuit. On the other hand, when the clock feed circuit is not feeding the clock, the first logic circuit is fed with a comparatively low first supply voltage. This makes the first logic circuit operate relatively slowly. However, the input signal to the first logic circuit remains at a low level or a high level because the clock is not fed to the flip-flop. This enables the main circuit to operate without any problems. That is, even in this case, normal operation of the main circuit is ensured, and in addition it is possible to achieve reduction in electric power consumption of the main circuit because the first logic circuit is fed with a comparatively low first supply voltage.

Moreover, for example, the control circuit so controls that, when an input signal to the main circuit undergoes an inversion, prior to the inversion, the first logic circuit is fed with a second supply voltage higher than the first supply voltage and, when the input signal to the main circuit remains at a fixed potential for a predetermined period of time or longer, the first logic circuit is fed with the first supply voltage.

When the input signal to the main circuit undergoes an inversion, that is, when the input signal to the first logic circuit undergoes an inversion, the first logic circuit is fed with a comparatively high second supply voltage. This makes the first logic circuit operate relatively fast, and thereby ensures normal operation of the main circuit. On the other hand, when the input signal to the main circuit remains at a fixed potential, that is, when the input signal to the first logic circuit remains at a fixed potential, the first logic circuit is fed with a comparatively low first supply voltage. This makes the first logic circuit operate relatively slowly. However, the main circuit operates without any problems because the input signal to the first logic circuit remains at a fixed potential. That is, even in this case, normal operation of the main circuit is ensured, and in addition it is possible to achieve reduction in electric power consumption of the main circuit because the first logic circuit is fed with a comparatively low first supply voltage.

Moreover, for example, the semiconductor device may be further provided with a power supply circuit including a power generation circuit that generates the first supply voltage, a voltage step-up circuit that generates the second supply voltage by stepping up a voltage derived from the first supply voltage, and a selection circuit that selects either the first supply voltage or the second supply voltage.

For example, when the first logic circuit is fed with the first supply voltage, the voltage step-up circuit may be made to stop its operation.

This eliminates unnecessary operation of the voltage step-up circuit, and achieves further reduction in electric power consumption.

To achieve the above object, according to the present invention, an electric appliance is provided with a semiconductor device, and the semiconductor device is provided with: a main circuit including a first logic circuit and a second logic circuit that is connected in a stage preceding or succeeding the first logic circuit and that operates from a first supply voltage equal to or lower than a supply voltage fed to the first logic circuit; and a control circuit that controls the supply voltage fed to the first logic circuit according to a state of an input signal to the first logic circuit.

It is to be noted that, in the present specification and claims, a “high” supply voltage indicates that, when the supply voltage is negative, the absolute value of the voltage is large, and a “low” supply voltage indicates that, when the supply voltage is negative, the absolute value of the voltage is small. Therefore, for example, a second supply voltage of −4V is higher than a first supply voltage of −3V.

As described above, the semiconductor device according to the present invention makes it possible to achieve reduction in electric power consumption while ensuring normal operation of the semiconductor device. Therefore, it is possible to make longer an operation time of a portable device operate employing such a semiconductor device.

### BRIEF DESCRIPTION OF THE DRAWINGS

FIG. 1 is a circuit diagram showing the configuration of the semiconductor device embodying the invention;

FIG. 2 is a timing chart showing the operation of the semiconductor device shown in FIG. 1;

FIG. 3 is a timing chart showing the operation of the semiconductor device shown in FIG. 1; and

FIG. 4 is a timing chart showing the operation of the semiconductor device shown in FIG. 1.

### DETAILED DESCRIPTION OF PREFERRED EMBODIMENTS

### First Embodiment

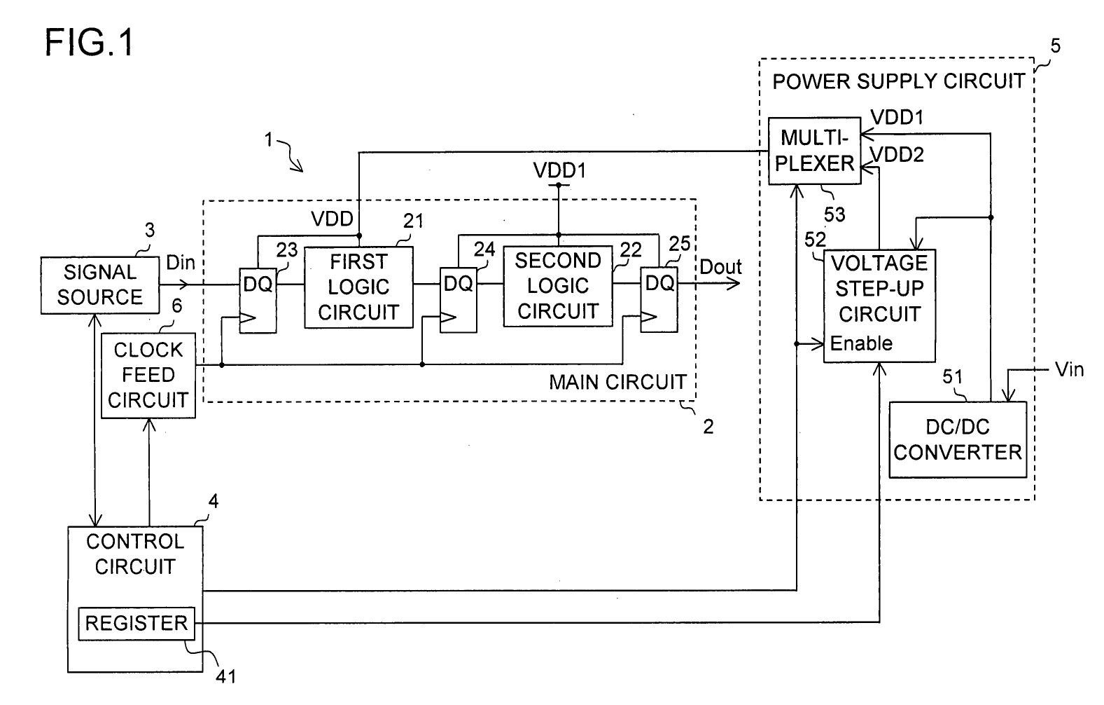

A first embodiment of the present invention will be described with reference to the accompanying drawings. FIG. 1 is a circuit diagram showing the configuration of the semiconductor device of the first embodiment.

The semiconductor device 1 includes as its principal components: a main circuit 2 composed of a sequential circuit that receives an input signal Din provided from a signal source 3 and outputs a signal Dout; the signal source 3; a control circuit 4 that is composed of a CPU (central processing unit), an MPU (micro processing unit), a DSP (digital signal processor), or the like, that performs predetermined calculation processing, and that adjusts a supply voltage fed to a first logic circuit 21 and a D-type flip-flop (hereinafter referred to as a “DFF”) 23 provided in the main circuit 2; a power supply circuit 5 that receives an input voltage Vin from the outside and feeds a first supply voltage VDD1 (e.g., 2V) to the circuits of the semiconductor device 1, and that feeds, in accordance with the control of the control circuit 4, the first supply voltage VDD1 or a second supply voltage VDD2 (e.g., 3V) that is higher than the first supply voltage VDD1 to the first logic circuit 21 and the DFF 23 provided in the main circuit 2; and a clock feed circuit 6 that generates a clock having a predetermined frequency (e.g., 100 MHz) to feed the clock to the main circuit 2. When the control circuit 4 provides the main circuit 2 with the input signal Din, it is possible to omit the signal source 3. Moreover, when the control circuit 4 provides the main circuit 2 with a clock, or when an unillustrated circuit (such as another CPU) provides the main circuit 2 with a clock, it is possible to omit the clock feed circuit 6. In that case, it can be considered that the control circuit 4 and the unillustrated circuit that provide the main circuit 2 with a clock double as a clock feed circuit.

The main circuit 2 is composed of the first logic circuit 21, a second logic circuit 22, and DFFs 23, 24, and 25. The DFF 23 is a positive edge-triggered D-type flip-flop that latches a signal provided to the D terminal thereof in synchronism with the rising edge of a clock signal, and that then outputs the latched signal from the Q terminal thereof. Needless to say, the positive edge-triggered DFF may be replaced with a negative edge-triggered DFF. The same applies to the DFFs 24 and 25.

The input signal Din provided to the main circuit 2 is inputted to the D terminal of the DFF 23, and the signal from the Q terminal of the DFF 23 is an input signal to the first logic circuit 21. The first logic circuit 21 is built as a combinational circuit behaving as a critical path of the main circuit 2, and the output therefrom is provided to the D terminal of the DFF 24.

The second logic circuit 22 is built as a combinational circuit, receives the signal from the Q terminal of the DFF 24 as an input signal thereto, and provides its output to the D terminal of the DFF 25. The DFF 25 outputs, from the Q terminal thereof, the output signal Dout of the main circuit 2. The clock feed circuit 6 is a circuit for feeding a clock generated thereby to the DFFs 23, 24, and 25, for example, and whether the generated clock is fed or not is controlled by the control circuit 4.

Specifically, the clock feed circuit 6 is so controlled that, when it receives a clock feeding signal (for example, a low level control signal) from the control circuit 4, it feeds a clock to the clock input terminals of the DFFs 23, 24, and 25; when it receives a clock feeding stop signal (for example, a high level control signal) from the control circuit 4, it stops feeding the clock to the DFFs 23, 24, and 25 (the potentials at the clock input terminals of the DFFs 23, 24, and 25 are fixed to a low level or a high level).

The power supply circuit 5 is composed of a DC/DC converter (a power generation circuit) 51 that receives the input voltage Vin from the outside and outputs the first supply voltage VDD1, a voltage step-up circuit 52 that steps-up the first supply voltage VDD1 and then outputs the second supply voltage VDD2, and a multiplexer (a selection circuit) 53 that receives the first supply voltage VDD1 and the second supply voltage VDD2 and then feeds the first supply voltage VDD1 or the second supply voltage VDD2 as a supply voltage to the first logic circuit 21 and the DFF 23.

By a switching operation performed by the multiplexer 53 as mentioned above, a supply voltage VDD fed to the first logic circuit 21 and the DFF 23 provided in the main circuit 2 is switched between the first supply voltage VDD1 and the second supply voltage VDD2. On the other hand, the second logic circuit 22 and the DFFs 24 and 25 invariably receive the first supply voltage VDD1 as their supply voltage.

The control circuit 4 provides the multiplexer 53 with a signal for controlling the switching operation performed by the multiplexer 53, and provides the voltage step-up circuit 52 with an enable signal for performing a step-up operation or a disable signal for stopping a step-up operation. Specifically, the enable signal denotes a high level signal to be fed to the enable input terminal (Enable) of the voltage step-up circuit 52, and the disable signal denotes a low level signal to be fed to the enable input terminal.

Moreover, the control circuit 4 has a register 41 incorporated therein. The register 41 stores data for setting the rate at which the voltage is stepped-up or the amount of stepped-up voltage (=VDD2−VDD1) of the voltage step-up circuit 52. Based on the data (the step-up rate or the amount of stepped-up voltage) stored in the register 41, the voltage step-up circuit 52 steps up the first supply voltage VDD1 to the second supply voltage VDD2. Note that the data stored in the register 41 is rewritable.

Moreover, the control circuit 4 controls the signal source 3 or receives information on the input signal Din from the signal source 3. This enables the control circuit 4 to recognize the voltage waveform of the input signal Din inputted to the main circuit 2.

When the same supply voltage is fed to the first logic circuit 21 and the second logic circuit 22, the time required by the second logic circuit 22 to change the level of a signal to be outputted therefrom to reflect variations in the level (logic level) of the signal inputted thereto (a delay time or a propagation delay time) is shorter than that required by the first logic circuit 21. In other words, the second logic circuit 22 operates faster than the first logic circuit 21. For example, in the first logic circuit 21 operating from the first supply voltage VDD1, the time required to change the level of a signal to be outputted therefrom (a signal to be outputted to the D terminal of the DFF 24) to reflect variations in the level of the signal inputted thereto (the signal inputted from the Q terminal of the DFF 23) is 14 nanoseconds. By contrast, in the second logic circuit 22 operating from the first supply voltage VDD1, the time required to change the level of a signal outputted therefrom (a signal outputted to the D terminal of the DFF 25) to reflect variations in the level of the signal inputted thereto (the signal inputted from the Q terminal of the DFF 24) is 8 nanoseconds.

Therefore, suppose that, when the same supply voltage is fed thereto, the frequency of the clock generated by the clock feed circuit 6 is gradually increased. Under these conditions, the frequency at which the second logic circuit 22 can operate normally is higher than the frequency at which the first logic circuit 21 can operate normally. Furthermore, the first logic circuit 21 behaves as a critical path which has the maximum delay time among the circuit paths together forming the main circuit 2.

The voltage value of the first supply voltage VDD1 is so set as to ensure normal operation of the second logic circuit 22. That is, the second logic circuit 22 can always provide a signal level in which a signal level outputted from the DFF 24 with the timing with which the clock starts rising is reflected to the D terminal of the DFF 25 by the time that the clock starts rising next time. From the viewpoint of reducing electric power consumption, it is preferable that the first supply voltage VDD1 be set as low as possible so long as the second logic circuit 22 can operate normally.

The first logic circuit 21 needs to provide a signal having a level in which a signal level outputted from the DFF 23 with the timing with which the clock starts rising is reflected to the D terminal of the DFF 24 by the time that the clock starts rising next time (i.e., the first logic circuit 21 needs to operate normally). However, when the supply voltage VDD is the first supply voltage VDD1, the first logic circuit 21 cannot provide a signal having a level in which variations in the level of the signal inputted thereto is reflected to the D terminal of the DFF 24 by the time that the clock starts rising next time (in other words, the voltage value of the first supply voltage VDD1 is so set that it does not allow the first logic circuit 21 to do so).

On the other hand, when the supply voltage VDD is the second supply voltage VDD2, the first logic circuit 21 can provide a signal having a level in which variations in the level of the signal inputted thereto is reflected to the D terminal of the DFF 24 by the time that the clock starts rising next time (in other words, the voltage value of the second supply voltage VDD2 is so set that it allows the first logic circuit 21 to do so).

Clock Feeding Stop Control

When the control circuit 4 provides the clock feed circuit 6 with a clock feeding signal, the clock feed circuit 6 feeds the clock generated thereby to the DFFs 23, 24, and 25. At this time, the control circuit 4 provides an enable signal to the voltage step-up circuit 52 to cause it to perform a step-up operation, and controls the multiplexer 53 in such a way that a line to which the voltage step-up circuit 52 feeds the second supply voltage VDD2 is connected to the power supply line of the first logic circuit 21 and the DFF 23. Therefore, in this case, the first logic circuit 21 and the DFF 23 are fed with the second supply voltage VDD2 as their supply voltage. This ensures normal operation of the first logic circuit 21, and thereby ensures normal operation of the main circuit 2.

On the other hand, when the control circuit 4 provides the clock feed circuit 6 with a clock feeding stop signal, the clock feed circuit 6 stops feeding the clock to the DFFs 23, 24, and 25. At this time, the control circuit 4 provides a disable signal to the voltage step-up circuit 52 to cause it to stop a step-up operation, and controls the multiplexer 53 in such a way that a line to which the first supply voltage VDD1 is fed is connected to the power supply line of the first logic circuit 21 and the DFF 23. Therefore, in this case, the first logic circuit 21 and the DFF 23 are fed with the first supply voltage VDD1 as their supply voltage. This reduces electric power consumption of the main circuit 2. Moreover, the input signal of the first logic circuit 21 is fixed to a low level or a high level, because no clock is fed to the DFF 23. This makes the main circuit 2 operate without any problems. That is, normal operation of the main circuit 2 is (practically) ensured.

Note that the above-described clock feeding stop signal is generated in a standby state, for example, where the function of the main circuit 2 is not needed.

### Second Embodiment

Next, a second embodiment of the present invention will be described. The circuit configuration of the semiconductor device of the second embodiment is the same as that shown in FIG. 1, and thus the description thereof is omitted. In the second embodiment, the control circuit 4 always provides the clock feed circuit 6 with a clock feeding signal. Here, the circuit configuration may be modified to make the clock feed circuit 6 always feed a clock to the DFFs 23, 24, and 25 regardless of the signal from the control circuit 4.

As described above, the control circuit 4 can recognize the voltage waveform of the input signal Din inputted to the main circuit 2 by controlling the signal source 3, or by receiving information on the input signal Din from the signal source 3. For example, suppose that, under the control of the control circuit 4, the signal source 3 outputs the input signal Din with one of three different level shifting patterns. Needless to say, the number of patterns of the input signal Din used in the present invention is not limited to three.

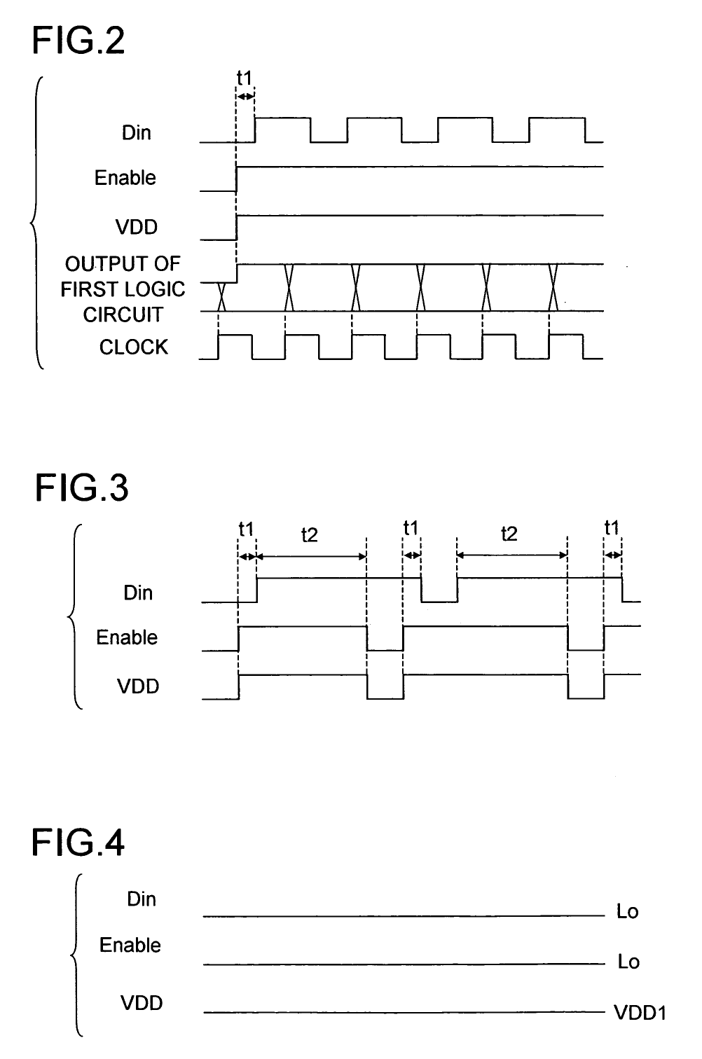

FIG. 2 shows the operation of the semiconductor device when the input signal Din has pattern 1. FIG. 2 shows, from top, the voltage waveforms of the input signal Din, the input signal to the enable input terminal (Enable) of the voltage step-up circuit 52, the supply voltage VDD, the output signal of the first logic circuit 21, and the clock outputted from the clock feed circuit 6. As shown in FIG. 2, the input signal Din having pattern 1 is a signal that begins, at some point in time, repeatedly undergoing an inversion (by which a signal potential (level) of the input signal is inverted from a low level to a high level, or from a high level to a low level).

At first, a low level signal is provided to the enable input terminal of the voltage step-up circuit 52, and the first supply voltage VDD1 is fed as the supply voltage VDD. At a predetermined time t1 before the time at which the input signal Din is first switched (inverted) from a low level to a high level, the control circuit 4 turns the signal to be inputted to the enable input terminal of the voltage step-up circuit 52 to a high level, and controls the multiplexer 53 in such a way that a line to which the voltage step-up circuit 52 feeds the second supply voltage VDD2 is connected to the power supply line of the first logic circuit 21 and the DFF 23. That is, prior to the inversion of the input signal Din, the supply voltage VDD is switched to the second supply voltage VDD2. Note that, as shown in FIG. 2, the output signal of the first logic circuit 21 varies in synchronism with the rising edge of the clock (it is needless to say that sometimes it does not vary).

FIG. 3 shows the operation of the semiconductor device when the input signal Din has pattern 2. FIG. 3 shows, from top, the voltage waveforms of the input signal Din, the input signal to the enable input terminal (Enable) of the voltage step-up circuit 52, and the supply voltage VDD. As shown in FIG. 3, the input signal Din having pattern 2 is a signal that repeatedly undergoes an inversion.

As described above with reference to FIG. 2, at a predetermined time t1 before the time at which the input signal Din is first switched (inverted) from a low level to a high level, the control circuit 4 turns the signal to be inputted to the enable input terminal of the voltage step-up circuit 52 to a high level, and controls the multiplexer 53 in such a way that a line to which the voltage step-up circuit 52 feeds the second supply voltage VDD2 is connected to the power supply line of the first logic circuit 21 and the DFF 23. As a result, the supply voltage VDD is switched to the second supply voltage VDD2.

However, when the potential of the input signal Din remains at a high level for a predetermined time t2 or longer, the control circuit 4 turns the signal to be inputted to the enable input terminal of the voltage step-up circuit 52 to a low level, and controls the multiplexer 53 in such a way that a line to which the first supply voltage VDD1 is fed is connected to the power supply line of the first logic circuit 21 and the DFF 23. As a result, the supply voltage VDD is switched to the first supply voltage VDD1.

Thereafter, the power supply circuit 5 is controlled in such a way that, at a time t1 before the time at which the input signal Din undergoes an inversion, the supply voltage VDD is switched to the second supply voltage VDD2, and that, when the potential of the input signal Din remains at a high level for a predetermined time t2 or longer, the supply voltage VDD is switched to the first supply voltage VDD1. Although not shown in the figure, when the potential of the input signal Din remains at a low level for a predetermined time t2 or longer, the power supply circuit 5 is controlled in the same manner as described above, that is, controlled in such a way that the supply voltage VDD is switched to the first supply voltage VDD1.

FIG. 4 shows the operation of the semiconductor device when the input signal Din has pattern 3. FIG. 4 shows, from top, the voltage waveforms of the input signal Din, the input signal to the enable input terminal (Enable) of the voltage step-up circuit 52, and the supply voltage VDD. As shown in FIG. 4, the input signal Din having pattern 3 always remains at a low level. In this case, the control circuit 4 makes low the level of the signal to be inputted to the enable input terminal of the voltage step-up circuit 52, and controls the multiplexer 53 in such a way that a line to which the first supply voltage VDD1 is fed is connected to the power supply line of the first logic circuit 21 and the DFF 23. As a result, the first supply voltage VDD1 is fed as the supply voltage VDD. Similarly, when the input signal Din remains at a high level, the first supply voltage VDD1 is fed as the supply voltage VDD.

When the input signal Din has pattern 1 or pattern 2, the input signal to the first logic circuit 21 (the output signal from the Q terminal of the DFF 23) repeatedly undergoes an inversion. Thus, the first logic circuit 21 needs to change the level of a signal to be outputted therefrom (a signal to be inputted to the D terminal of the DFF 24) to reflect variations in the level of the signal inputted thereto. However, as described above, prior to the inversion of the input signal Din, the first logic circuit 21 is fed with the second supply voltage VDD2 as its supply voltage. This ensures normal operation of the first logic circuit 21, and thereby ensures normal operation of the main circuit 2.

Moreover, like a part of pattern 2 or like pattern 3, i.e., when the potential of the input signal Din remains at a high level or a low level for a predetermined time t2 or longer, the control circuit 4 turns a signal to be inputted to the enable input terminal of the voltage step-up circuit 52 to a low level, and controls the multiplexer 53 in such a way that a line to which the first supply voltage VDD1 is fed is connected to the power supply line of the first logic circuit 21 and the DFF 23. When the input signal Din remains at a fixed potential, the input signal to the first logic circuit 21 also remains at a low level or a high level. Thus, the main circuit 2 operates without any problems. That is, normal operation of the main circuit 2 is (practically) ensured. In this case, the first logic circuit 21 and the DFF 23 are fed with the first supply voltage VDD1 as their supply voltage. This reduces electric power consumption of the main circuit 2.

For example, suppose that the semiconductor device 1 is incorporated in an image processing apparatus (not shown) such as a digital camera, and that the main circuit 2 is a sequential circuit for performing image processing. In this case, the image processing apparatus rarely performs image processing on a constant basis, and, when it is, for example, in a state (a still image playback mode) where the image displayed on the display screen (not shown) remains unchanged for a while (e.g., for a few seconds), a pattern 3-like input signal Din is often provided to the main circuit 2. In this state, stepping down the supply voltage of the first logic circuit 21 behaving as a critical path to the first supply voltage VDD1 is highly effective in reducing electric power consumption.

Moreover, the data (data for setting the step-up rate or the amount of stepped-up voltage of the voltage step-up circuit 52) stored in the register 41 is rewritable. This makes it possible to flexibly cope with design and specification changes. That is, it is possible, if necessary, to vary the second supply voltage VDD2 to be outputted from the voltage step-up circuit 52.

Note that the second logic circuit 22 may be located in a stage preceding the first logic circuit 21, and that another logic circuit (not shown) operating from a low-voltage supply voltage VDD1 may be included in the main circuit 2. Moreover, a circuit path other than a combinational circuit that behaves as a critical path may be included in the first logic circuit 21.

### Modifications

The first and second embodiments described above deal with cases where, only when an enable signal is outputted from the control circuit 4, the voltage step-up circuit 52 is brought into an enable state and performs a step-up operation. It should be understood, however, that the voltage step-up circuit 52 may be always in an enable state. Moreover, at a predetermined time t3 (t3>t1; t3 is not shown in FIGS. 2 and 3) before the time at which the input signal Din undergoes an inversion, the voltage step-up circuit 52 may be brought into an enable state. These modifications are effective when the rising time of the second supply voltage VDD2 particularly matters.

Moreover, the first and second embodiments described above deal with cases where the DFF 23 is fed with the supply voltage VDD as its supply voltage. It should be understood, however, the supply voltage of the DFF 23 may be fixed to the first supply voltage VDD1. However, from the viewpoint of making higher a clock frequency at which the first logic circuit 21 can operate normally by making a propagation delay time of the DFF 23 as short as possible, it is preferable that the supply voltage VDD be fed to the DFF 23 as its supply voltage.

According to the present invention, it is possible to achieve reduction in electric power consumption. Therefore, the present invention is suitable for application in semiconductor devices such as SOCs (systems on a chip) that require reduction in electric power consumption from the viewpoint of preventing increase in temperature. Moreover, according to the present invention, it is possible to achieve reduction in electric power consumption. Therefore, a semiconductor device according to the present invention is suitable in application in various electric appliances such as movable communications devices and portable devices including cellular phones and PHSs (personal handyphone systems) that require reduction in electric power consumption, and information processing devices typified by personal computers.

What is claimed is:

1. A semiconductor device comprising:
a main circuit including
a first logic circuit and
a second logic circuit that is connected in a stage preceding or succeeding the first logic circuit and that operates from a first supply voltage equal to or lower than a supply voltage fed to the first logic circuit; and
a control circuit that controls the supply voltage fed to the first logic circuit according to a state of an input signal to the first logic circuit.

2. The semiconductor device of claim 1 further comprising:
a clock feed circuit that can feed a clock to a flip-flop provided in a stage preceding the first logic circuit,
wherein the control circuit so controls that,
when the clock feed circuit is feeding the clock, the first logic circuit is fed with a second supply voltage higher than the first supply voltage and,
when the clock feed circuit is not feeding the clock, the first logic circuit is fed with the first supply voltage.

3. The semiconductor device of claim 1,
wherein the control circuit so controls that,
when an input signal to the main circuit undergoes an inversion, prior to the inversion, the first logic circuit is fed with a second supply voltage higher than the first supply voltage and,
when the input signal to the main circuit remains at a fixed potential for a predetermined period of time or longer, the first logic circuit is fed with the first supply voltage.

4. The semiconductor device of claim 2, further comprising:
a power supply circuit including
a power generation circuit that generates the first supply voltage,
a voltage step-up circuit that generates the second supply voltage by stepping up a voltage derived from the first supply voltage, and
a selection circuit that selects either the first supply voltage or the second supply voltage.

5. The semiconductor device of claim 3, further comprising:
a power supply circuit including
a power generation circuit that generates the first supply voltage,
a voltage step-up circuit that generates the second supply voltage by stepping up a voltage derived from the first supply voltage, and
a selection circuit that selects either the first supply voltage or the second supply voltage.

6. The semiconductor device of claim 4,
wherein, while the first logic circuit is fed with the first supply voltage, the voltage step-up circuit is kept out of operation.

7. The semiconductor device of claim 5,
wherein, while the first logic circuit is fed with the first supply voltage, the voltage step-up circuit is kept out of operation.

8. An electric appliance comprising a semiconductor device,
wherein the semiconductor device comprises:
a main circuit including
a first logic circuit and
a second logic circuit that is connected in a stage preceding or succeeding the first logic circuit and that operates from a first supply voltage equal to or lower than a supply voltage fed to the first logic circuit; and
a control circuit that controls the supply voltage fed to the first logic circuit according to a state of an input signal to the first logic circuit.
